(19) United States
(12) Patent Application Publication
(10) Pub. No.: US 2004/0055153 A1
(43) Pub. Date: Mar. 25, 2004

(54) Method for producing a molding with an integrated conductor run, and a molding

(76) Inventors: Franz Zahradnik, Herzogenaurach (DE); Uli Hartmann, Paderborn (DE); Knuth Gotz, Mistelbach (DE); Gerhard Reichinger, Rednitzhembach (DE)

Correspondence Address: LERNER AND GREENBERG, P.A., POST OFFICE BOX 2480, HOLLYWOOD, FL, 33022-2480, US

(21) Appl. No.: 10/647,542

(22) Filed: Aug. 25, 2003

Related U.S. Application Data
(63) Continuation of application No. PCT/EP02/01896, filed on Feb. 22, 2002.

(30) Foreign Application Priority Data
Feb. 22, 2002 (DE) 101 09 087.0

(51) Int. Cl. H05K 3/02; H05K 1/11

(52) U.S. Cl. 29/846; 29/848; 174/255; 174/261

(57) ABSTRACT

In the method for producing a molding with an integrated conductor run, a conductor run is produced on a mount component in particular with the aid of gas flame spraying or cold gas spraying. For this purpose, the surface of the mount component is selectively treated in a corresponding manner to a profile that is provided for the conductor run, such that the surface has areas of different adhesion. A germination layer is applied to the profile that is provided for the conductor run, and the actual conductor run is then in turn applied to the germination layer. This makes it possible to produce a molding with an integrated conductor run pattern in a highly flexible and cost-effective manner. Specific customer wishes can be implemented at short notice and without any problems by a change to the conductor run layout, particularly in the field of motor vehicles.

### CROSS-REFERENCE TO RELATED APPLICATION

This application is a continuation of copending International Application No. PCT/EP02/01896, filed Feb. 22, 2002, which designated the United States and was not published in English.

### BACKGROUND OF THE INVENTION

Field of the Invention

The invention relates to a method for producing a molding with an integrated conductor run, in particular to a method for producing a motor vehicle molding, and to a molding that is produced using the method.

In the field of motor vehicles, in particular in the field of passenger vehicles, it is desirable to have a reordering duration which is as short as possible, that is to say as short a time interval as possible between a final customer placing an order and the delivery of a motor vehicle from the production site. To do this, the components that are supplied to the production site must have a high degree of prefabrication. For the supplier, this results in that differently configured components with a high degree of integration density, that is to say with different functions, must be produced within a very short time.

In the area of the power supply system for motor vehicle electrical systems, a number of electrical conductors are nowadays normally joined together to form a prefabricated cable harness.

International Patent Disclosure WO 99/61282 discloses the integration of a cable harness directly in a door module, so that the electrical components which are disposed in the door just have to be connected to the rest of the vehicle power supply system by plugging them in. This avoids complex installation of the cable harness in the door area when the door is being fitted to the bodywork. The door module has grooves incorporated in it for routing the cable harness, the individual conductors in the cable harness being laid in the grooves. This has the disadvantage that the grooves have to be incorporated in the door module in a comparatively complex manner, and that changes to the routing of the cable harness also necessitate changes to the grooves. Owing to the wider range of electrical equipment model variants in the field of motor vehicles, this results in that there is little flexibility to react to particular customer wishes and that a high degree of effort is required to implement such customer wishes.

### SUMMARY OF THE INVENTION

It is accordingly an object of the invention to provide a method for producing a molding with an integrated conductor run, and a molding that overcome the above-mentioned disadvantages of the prior art methods and devices of this general type, which is flexible and cost effective.

With the foregoing and other objects in view there is provided, in accordance with the invention, a production method. The method includes providing a motor vehicle molding for producing an end product such as a door, a door module, a door panel, a dashboard part, or a dashboard. A surface of the motor vehicle molding is treated selectively in a manner corresponding to a profile provided for a conductor run, such that the surface has areas of different adhesion. A germination layer is applied to the profile provided for the conductor run, and the conductor run is applied to the germination layer resulting in the conductor run being integrally connected to the motor vehicle molding.

The invention provides for the conductor run to be applied directly to a mount component, in particular of a motor vehicle molding, so that the conductor run is integrated on the mount component. In this case,

a) the surface of the mount component is treated selectively in a corresponding manner to a profile which is provided for the conductor run, such that the surface has areas of different adhesion;

b) a germination layer is applied in the profile which is provided for the conductor run; and

c) the conductor run is applied to the germination layer.

In this context, the conductor run is, in particular, a conductor run in a cable harness for a power supply system in the field of motor vehicles. The molding may be any desired motor vehicle component that is intended for routing of a cable harness or for configuration of electrical components. The molding is, for example, a door, a door module, a semi-finished product (panel) or else the dashboard area. The molding component may be composed of any desired material, for example metal or plastic. The mount component may be identical to the molding, or may be a part of it.

The method is not restricted to the field of motor vehicles but is generally suitable for the production of a conductor run on components from widely differing technical fields. In addition to use for a vehicle power supply system, the method can also be used in particular for producing a conductor run for electrical domestic appliances and for electrical toys, for example remotely controlled electric cars.

Step a) is in this case based on the idea of producing discrete conductor run structures flexibly, quickly and without incurring major costs on surfaces of any desired shape, without any need to incorporate, for example, grooves or other cable guides in the mount component. Step a) thus defines the desired conductor run structure. Step b) is based on the idea of providing a germination or adhesion promoter layer for secure adhesion of the conductor run on the mount component. The sequence of steps a) and b) can also be interchanged, that is to say a germination layer can first be applied, for example by application of a conductive powder over a large area with this, however, initially adhering uniformly over the entire surface. The surface of the mount component is then locally melted, for example by selective heat treatment, so that the germination layer powder adheres firmly in these areas. For this variant, the mount component is composed of plastic or preferably has a coating or a surface of plastic, such as a varnish or an adhesive.

The preferably metallic germination layer may also be regarded as an adhesion promoter layer between the surface of the mount component and the conductor run. This allows conductor run patterns to be produced reliably on mount components composed of widely differing materials, without any risk of them becoming detached. The conductor run is thus applied in step c) with good bonding to the mount component.

This novel method allows the desired conductor run pattern to be produced directly on the mount component, on mount components of any desired configuration and any desired shape, depending on the desired requirement. There is no need for manual routing of individual cables or cable harnesses. In fact, a high degree of automation can be achieved. In principle, the method allows the entire power supply system for a motor vehicle to be formed quickly, flexibly and cost-effectively, so that it is possible to produce a vehicle power supply system without any cables. Direct integration of mount components without any projecting parts result in the conductor run which is applied furthermore being well protected against mechanical damage, for example by being bitten by rodents.

In the step after step a), the areas which are intended for the conductor run structure can optionally be formed to be adhesive. Alternatively—if there is a large-area adhesive substrate, for example an appropriate varnish layer—the adhesion characteristic of the complementary areas that are not intended for the conductor run pattern can be reduced.

The conductor run is preferably applied by a beam thermal/kinetic application method or spraying method. The expression beam thermal/kinetic application methods generally refers to application methods in which a particle beam, namely the material to be applied, in particular copper particles, is directed at the mount component with kinetic energy and after heat has been supplied. A method such as this is also referred to generally as thermal spraying, as is described in DIN 32530. Masks, electromagnetic fields or what are referred to as sheathed flows may be provided for application in as objective a manner as possible. The expression “thermal” should in this case be regarded as meaning that the particles in the particle beam in particular soften, start to melt or melt, or that they are at least heated to such an extent that they cause a thermal change in the surface of the mount component. The thermal change may contain a reduction in the surface hardness, softening, or the surface starting to melt. The expression “kinetic” should be understood as meaning that the impulse of the particles is sufficiently high that they are at least partially pressed into the surface—which surface may possibly have previously been softened—when they arrive at this surface.

What is referred to as gas flame spraying is particularly suitable for use as the application method. In this spraying method, the conductor run material to be applied, in particular copper, is at least partially melted during the spraying process. The heat that is introduced preferably at least partially melts the germination layer so that the germination layer and the conductor run material are closely and preferably integrally joined. The layer thickness of the conductor run may be made to be appropriately thick in terms of having sufficiently high electrical conductivity by suitable choice of the spraying parameters or else by spraying the surface two or more times. Gas flame spraying allows very quick and economic application of the conductor run, with comparatively little technical effort.

What is referred to as cold gas spraying is also suitable, in addition to gas flame spraying. This method is also referred to by the expression beam plating. In this method, particles strike the mount component with very high kinetic energy. Some of the particles are in this case accelerated to the speed of sound, or more. The diameter of the particles, for example copper particles, is, for example, in the range between 10 and 100 μm. Cold gas spraying allows mass to be applied at a high rate. Owing to the high kinetic energy, comparatively low temperatures are sufficient, so that the thermal load on the mount component and on the spraying material, that is to say the particles, is low. Overall, a high spraying rate and high application efficiency are possible, and thick layers can be applied.

One major advantage in forming the conductor run structure by thermal/kinetic application methods, in particular gas flame spraying, is the high flexibility, since any desired conductor run structures can be produced by the spraying process, even on complex moldings. Furthermore, the conductor run structure can be produced quickly. Furthermore, the spraying process has the advantage that the mount component can be treated selectively and, in particular, without the use of chemicals. For selective treatment, the beam is preferably aimed at a particular point by use of masks, electromagnetic beams or by sheathed flows. In order to produce a complex conductor run structure as quickly as possible, two or more tool or spraying heads are preferably operated at the same time alongside one another in a grid configuration.

In the application method, the particles are normally carried by a carrier gas, which is preferably an inert gas such as nitrogen. This keeps the risk of undesirable oxidation of the particles low, so that the conductor run which is produced has high conductivity.

In addition to conductive particles, nonconductive impurities, in particular silicon, are expediently additionally added to the particle beam. These impurities, which preferably make up between 0.01 and 1.6% by weight, have an advantageous effect on the conductivity of the conductor runs that are produced, without changing the mechanical characteristics.

As an alternative to thermal/kinetic application methods, the conductor run can in principle also be applied by other methods to the germination layer that is formed. In particular, the mount component can be drawn through a melt bath, with the material sticking only to the germination layer and with the conductor run being formed.

For application from the melt, the liquid material can also be applied by a form of wave soldering. In addition, the conductor run can also be applied by application of a conductive paste, by application of a conductive powder or by a lamination process. When applying the conductor run from a conductive powder, it is important for the powder particles to be disposed as densely as possible, in order to achieve adequate conductivity. In order to improve the conductivity, the conductor run is preferably heated after the application of the powder, so that the individual particles are baked to one another in the form of a sintering process. In particular, a high current is passed through the conductor run for this purpose. All the methods have the common feature that the conductive material that is applied is applied only in the area of the conductor run structure, thus forming the desired conductor run.

In one preferred embodiment, two or more of the method steps a) to c) are carried out by a processing apparatus, thus allowing the conductor run structure to be produced quickly and economically. For this purpose, the processing apparatus has, for example, a heat source in order to change the adhesion characteristic of the surface by heat treatment. At the same time, a supply unit for copper particles to form the germination layer is integrated in the apparatus. Thirdly, a spraying head can also be integrated at the same time, in order to produce the conductor run. Alternatively, both the germination layer and the conductor run can be produced by the spraying head.

A number of advantageous alternatives for varying the adhesion characteristic after step a) are possible. According to one preferred refinement, the mount component is coated with a substance that can be cross-linked, and whose adhesion characteristic is varied by subsequent cross-linking. Elastomers in particular can be used as substances that can be cross-linked. Examples of this are a rubber coating or silicone. Rubber coating is preferably used as the surface material. The rubber coating sticks to the area that is not cross-linked, for the application of the germination layer.

As an alternative to this, a substance that can be cured, such as an epoxy resin, polyurethane or cyanoacrylate, is preferably provided as the surface material for this purpose. Furthermore, it is also possible to use ceramic substances, whose advantages are their high temperature resistance. They are thus particularly suitable for routing a conductor run to a sensor in an area where there is a severe temperature load, for example in the vicinity of a combustion chamber or in the vicinity of brakes.

In a further preferred embodiment, the adhesion characteristic is varied by application of an, in particular, chemically active substance to the surface material. The chemically active substance is used, for example, to cross-link a surface material that can be activated chemically, for example a suitable rubber coating. Alternatively, it is also possible to provide for a solvent, for example, to be applied as chemically active substance to a plastic surface. The plastic surface is, for example, a painted layer that is applied to a metallic or ceramic mount component.

In a further preferred alternative, the adhesion characteristic is varied by heat treatment, in particular by thermal or electromagnetic radiation. In particular, the surface material is laser-treated. A halogen radiating element, preferably with a power of between 50 and 70 watts, can also be used to produce the thermal radiation. Lenses or shutters can be used for focusing in this case. The simultaneous use of two or more radiating elements is advantageous. The heat treatment somewhat softens the surface, in particular the plastic surface, of the mount component. A copper powder, for example, is then applied to these softened surface areas in order to form the germination layer. The irradiation process allows the surface material to be treated very quickly and flexibly, with high spatial resolution. As an alternative to irradiation using a radiation source, the heat can also be introduced by a flame or by hot air.

The adhesion characteristic can also be varied in an expedient manner by direct selective application of an adhesion layer to the surface. A painted layer or an adhesion layer is applied, for example, for this purpose. The adhesion characteristic of the painted layer may in this case also be influenced by the introduction of heat. The selective application process is in this case based on the idea of providing a painted layer on the mount material only in areas in the intended conductor run profile, and not over the entire surface. This leads to material and cost savings. In this case, provision can be made for the germination layer to be produced in accordance with step b) at the same time that the adhesion layer is applied, for example by the paint that is to be applied containing metallic particles which act as an adhesion promoter for the conductor run.

According to a further preferred variant, the surface material is electrostatically charged in order to produce the adhering conductor run structure. A suitable material, for example graphite powder, is then applied to the electrostatically charged conductor run structure, as is known by way of example from the field of laser printing.

Depending on the condition of the mount component, it is advantageous to form the adhesion characteristic for the mount component to be provided in an area which is independent of the desired conductor run structure, in particular over a large area, with a specific surface material whose adhesion characteristic is then varied selectively. The surface material is applied, for example, by a coating process. The distribution of the surface material over a large area, in particular over the entire mount component, makes it possible to produce any desired conductor run structures flexibly and at low cost. To do this, the adhesion characteristic of the surface material is varied only in the area of the desired conductor run profile. The conductor run profile is therefore not defined until immediately before the application of the actual conductor run and does not involve any complex actions, for example by incorporating grooves in the mount component. The germination layer is preferably applied using one of many alternative processes. The germination layer is also referred to as a promoter layer, and ensures good bonding of the conductor run to the mount component.

In particular, provision is made for a powder, in particular a copper powder, to be applied to the surface of the mount component. This is done, for example, by application over a large area with those surface areas on which there is no adhesion subsequently being blown away. The powder can also be applied specifically by a small tube, which is disposed, for example, immediately behind the radiation source (halogen radiating element), by which the adhesion characteristic is varied. Furthermore, the mount component can also be drawn through a powder bath. The powder is in this case pressed on, for example, by active circulation of the powder in the powder bath or by shaking the powder onto the mount component. As a further preferred alternative, provision is made to apply a metallic suspension to the mount component. The metallic suspension contains metal particles distributed in a fluid. The fluid is evaporated or is absorbed by the material of the mount component, and the metal particles stick to the mount component selectively. The application process is carried out, for example, by nozzles or pins, such as those that are used for plotters.

The germination layer is preferably itself intrinsically electrically conductive. In principle, a nonmetallic and nonconductive germination layer can also be applied, provided that it is suitable for use as an adhesion promotion layer for the subsequent application of the conductor run.

The germination layer preferably has interruptions in the profile that is provided for the conductor run. The germination layer is therefore not applied over the entire area of the conductor run, but only in places. The germination layer may in this case have a shaded character, a diamond-shaped character, a honeycomb structure or a dotted character. The conductor run cannot be bonded to the mount component in the area of the interruptions. These non-adhering areas are bridged by the conductor run. This requirement is used for length or tolerance compensation, that is to say for example to compensate for length differences between the conductor run and the mount component caused by different thermal coefficients of expansion, without the conductor run being damaged. Overall, this measure makes the conductor run structure elastic.

The conductor run is preferably at least partially applied on a compensating layer that is connected to the mount component in a floating manner—that is to say only loosely. The floating mounting of the compensating layer with the conductor run applied to it is used to compensate the tolerances where torsional or shear stresses occur in the mount component, or else in a transitional area between two mount components. The floating mounting of the compensating layer on the mount component results in any stresses which may occur not being transmitted, or being transmitted only to a minor extent, to the conductor run, so that the conductor run is only slightly loaded and remains undamaged. The compensating layer is, for example, formed by a suitable rubber coating, which is detached from the mount component after the cross-linking process. Adjacent to the compensating layer, the conductor run is applied to a layer that is firmly connected to the mount component, for example an epoxy resin layer, or else is applied directly to the mount component.

In order to improve the conductivity, one advantageous variant provides for the material structure of the already applied conductor run to be varied. This is done, for example, by heat treatment of the conductor run, in particular using a laser, or else by applying pressure to it.

A further coating is expediently applied to the conductor run which has been applied. This is used optionally or in conjunction to increase the conductivity or as a protective layer against corrosion and/or as an insulation protective layer. A “PU” material or else rubber, for example, is applied to the conductor run as a corrosion protective layer. However, the conductor run itself may also be composed of a corrosion-resistant material, for example of a tin-bronze alloy. This then has the advantage that the conductor run can be contacted directly at any desired positions.

In particular after the application of the conductive material, excessively applied material and/or impurities are expediently removed by a cleaning process. To do this, the mount component is treated, for example, with a liquid or else with compressed air in a rinsing process. As an alternative to this, mechanical cleaning methods can be used, such as brushing or else laser treatment.

In order to achieve a reliable and permanent connection between the conductor run and the mount component, the adhesion of the conductor run is increased by a suitable fixing process. In the embodiment variant using a rubber coating, this is done, for example, by the conductor run area, which is initially not cross-linked, being cross-linked by vulcanization. The vulcanization is preferably in this case achieved by heat treatment, which is carried out at the same time as the application of the conductive layer, for example by applying a hot copper powder.

In order to achieve as high a functional density as possible, the conductor run or two or more conductor runs is or are applied such that an electrical functional component is produced. This is, for example, a capacitor, a coil or else a resistor. The conductor runs are formed with suitable geometric shapes for this purpose. For example, the conductor run cross section is varied in order to produce a specific resistance. In order to form a capacitor with a suitable capacitance, an appropriate capacitor area is predetermined by the conductor run or by a specific subarea of the conductor run, and the conductor run is routed suitably in order to produce a coil. The conductor runs may alternatively be in the form of a shielding. The functional component is preferably also in the form of a safety-relevant sensor. For example, capacitance changes to a capacitor which is formed by the conductor runs is used in the area of an external bodywork panel as an indication of deformation, and the triggering of an airbag is initiated.

In a particularly preferred refinement, two or more conductor runs are disposed one above the other in layers. This on the one hand keeps the amount of space required in the area small, and at the same time makes it possible to produce electrical functional components, such as capacitors.

In the case of complex conductor run patterns, care must be taken to ensure that the risk of arcing is avoided, in particular by suitable routing of the conductor runs, that is to say by geometric measures. The risk of arcing occurring is a particular factor with 42 V power supply systems in the field of motor vehicles. The following measures in particular are preferably provided in this case. The conductor runs are at a sufficient distance from one another, especially in critical areas. They are therefore provided with a wide grid size, particularly in areas where there is a high tendency to arcing, for example in contact areas, while a narrow grid size is produced in area where there is no danger. At least one additional conductor run is disposed between conductor runs between which there are potential differences, and is used as a sensor, for example for the occurrence of an increased temperature and hence of an arc. The conductor run which is disposed between conductor runs between which there are potential differences is part of a disconnection circuit, so that the relevant conductor runs can be disconnected from the voltage supply when an arc occurs. In the case of a three-dimensional multilayer structure, in which two or more conductor runs are disposed one above the other, a suitable grid size is provided not only in two dimensions but also in three dimensions for the conductor runs. This is done in particular by disposing the conductor runs offset with respect to one another, so that the conductor run in the upper level is disposed above an insulation strip between two conductor runs in the level located underneath. Contact points are preferably provided disposed in a zigzag or sawtooth pattern, so that the creepage distance between the contact points is as long as possible and, at the same time, the grid of the contact points (connection grid) is kept as small as possible.

In one advantageous embodiment, large-area conductive levels are formed, are disposed in layers, are part of an electrical power supply system, and carry out different functions for the vehicle power supply system. The conductive levels are disposed one above the other and extend parallel to the mount component. The embodiment variant is based on the idea of allowing contact to be made with electrical components independently of their position by large-area conductive levels. For example, the supply voltage for the electrical component can be tapped off at virtually any desired positions from the individual conductive levels. The individual conductive levels in this case carry out various functions for the vehicle power supply system. In particular, two levels are at different potentials, and other levels are used as a data bus line.

If only conductive levels are disposed on the mount component, then these each define a conductor run and the conductor run structure covers a correspondingly large area as a level. It is also possible to combine the conductive levels, which are disposed in layers, with discrete individual conductor runs, that is to say individual conductor runs which do not cover a large area. The conductive levels are preferably in the form of electrical functional components, such as capacitors, or sensors, in the same way as the discrete conductor runs.

In order to allow the conductor run on the molding to be connected to the rest of the vehicle power supply system, for example via a plug connection, in a simple manner, one preferred development provides for the conductor run not to be connected completely to the mount component, but to be able to be disconnected from it or lifted off it in one subarea. This is preferably achieved by applying an isolating element or an isolating layer under the conductor run. As an alternative to this, a piece of the conductor run area is treated in such a way that the adhesion to the mount component is detached in the subarea. This is done, for example, by heat treatment of the rubber coating. In order to allow partial disconnection capability, provision is also preferably made for different surface materials to be disposed alongside one another in the conductor run area, and for the capability for one of the surface materials to be detached from the mount component, for example after suitable treatment. In a further preferred refinement an extension, to which the conductor run extends, is applied before the conductor run is applied to the mount component, thus forming a type of pigtail. The pigtail is used, for example, to pass the cable harness out of the door area to the rest of the bodywork of the motor vehicle.

In order to make electrical contact with a connecting conductor easily, one conductor end of the conductor is preferably placed on the area of the conductor run structure and is electrically conductively connected to the conductor run when the latter is subsequently applied. In this case, a direct integral connection is produced between the connecting conductor and the conductor run since the connecting conductor is “coated” with the conductor run. There is no need for any subsequent soldering process. If the conductor run is applied under the influence of heat, then there is no need to strip the insulation off the end of the connecting conductor. In fact, the insulation will be destroyed by the application of the conductor run.

In order to make a reliable contact, the conductor ends of the connecting conductors are in this case suitably shaped to produce connection areas and contact areas that are as large as possible. This is done, for example, by inclined surfaces, or by forming a dovetail, triangular or zigzag shape. The conductor ends are in this case expediently beveled or have a lug attached. Alternatively or additionally, the conductor ends are preferably provided with recesses or holes, for example by stamping. In general, it is possible to use the application method for the conductor runs to make contact between two conventional conductors whose conductor ends are preferably suitably shaped for this purpose.

In order to produce a contact plug, the invention preferably provides for a plug molding to be fitted to the mount component, and this then to be at least partially covered or coated with a piece of the conductor run. The plug molding is in the form of an insert part composed of metal or plastic that, for example, has the contour of a plug pin or of a plug socket. The contour is covered by the conductor run. All that needs then be done to make contact with the conductor run is also to fit a correspondingly configured mating plug to the contact plug.

In general, this allows the plug system to be produced in which the shape, orientation and grid size of the individual contact plugs can be chosen virtually as required by appropriate configuration of the plug molding. This also makes it possible, in particular, to provide connections and codings that are self-locking and/or cannot be incorrectly connected.

The direct integral contact with the conductor run while it is being applied can also be used to make contact between the component mounts or circuit mounts or to make contact with connections for electrical appliances, such as motors, loudspeakers and the like. In this case, the invention provides in particular for the conductor run to make contact with the circuit mount, for example a printed circuit board, or a circuit mount assembly. This is done by incorporating a contact element, for example a contact pin, in the circuit mount or in the circuit mount assembly, with the conductor run making contact with the contact pin. The individual circuit mounts in a circuit mount assembly make contact with one another via the contact pin. The contact pin is in this case either configured to be continuously conductive or has insulated areas, and may also be in the form of a socket. Instead of the contact pin, a contact socket can also be used, or contact plates may be used, and are pressed against one another.

As an alternative to making contact during the application of the conductor run, the contact can also be made with a contact pin by pressing against the conductor run that is produced or by forming an insulation-displacement terminal contact, or other contacts.

In one preferred refinement, contact is made with an electrical component by the conductor run which is produced by the beam application method. The component is in this case disposed, for example, on a printed circuit board. This measure makes it possible to replace the soldering or conductive adhesive processes that are normally used nowadays for making contact with components.

In the field of motor vehicles, it is often necessary to pass an electrical cable through a component, for example a door panel, in order to pass the cable from the door to a control unit inside the passenger compartment or in the engine bay. In order to pass the conductor run through easily, provision is expediently made for a contact element to be passed through the component and for the conductor run to make contact with the contact element on both sides. The conductor run is in this case expediently once again directly integrally connected to the contact element during the application process.

Since the component often separates a wet area from a dry area, the contact element is expediently passed through the component such that a seal is formed. The contact element is for this purpose in the form of a metal rivet, for example, and is pushed into a nonconductive component, forming a seal. This measure avoids the necessity for the configuration of a grommet, as is conventionally provided when cables pass through such components. If the component is conductive and, in particular, metallic, then the contact element is preferably surrounded by an insulation layer or, for example, a rubber grommet.

In order to allow the conductor run to be applied in a simple manner even on moldings with a complex geometry, one particularly advantageous refinement provides for the conductor run first to be applied to the mount component and for this subsequently to be changed to the desired final shape of the molding by a forming process, for example by thermoforming. The mount component is thus preferably in the form of a semi-finished product, which is either completely planar or already has the contours applied to it in advance. The application of the conductor run before a forming process allows the described method to be carried out in a simple manner, for example in the fender area or in other areas with small radii.

The conductor run is in this case expediently of such a size in the forming area of the mount component that the conductor run has the desired electrical characteristics after the forming process. For example, the conductor run is applied with a greater thickness in the forming area than in the rest of the area. This prevents cracking of the conductor run during the forming process, for example during thermoforming, and ensures that the conductor run has an adequate thickness in the final form. The layer thickness is expediently matched to the application. In the field of motor vehicles, the layer thicknesses that are applied are typically between 20 μm and 1 mm.

In one expedient refinement, the conductor run is applied to the surface of an elongated molding, such as an electrical cable, a flexible tube, a tube or a pipe. This offers many configuration options for normally elongated moldings, and these moldings can be provided with an additional function. For example, the outer surface of an electrical cable, in particular a foamed-in-place cable, can be coated completely with the conductor run, so that the conductor run provides shielding. In this case, the coating is preferably applied by two or more spray nozzles that are disposed alongside one another.

As an alternative to this, provision is preferably made for two or more discrete conductor runs, which are routed parallel alongside one another, to be formed. These may also be disposed on the inner surface of a flexible tube or of a tube or pipe. For this purpose, the conductor run is applied to the inner surface by a suitable spray nozzle, for example during the process of extruding a flexible plastic tube. Conductor runs can be disposed on the inner surface of a tube or pipe, for example for empty conduits for building installations, so that an electrical connection is also produced at the same time via the conductor run on the empty conduit.

For economical and low-cost production of the molding with the integrated conductor run, it is generally advantageous to keep the amount of material required as small as possible. This is achieved in particular by the now described measures. The grid size of the germination layers for two or more conductor runs is chosen to be small, in order to choose the ratio of the surface area of the conductor runs to the surface area covered during the spraying process to be high. The conductor runs are configured to be broad and short in height. The conductor runs are preferably combined in corridors, whose width corresponds essentially to the width of the beam used in the spraying process, or the width of the beam is matched to the width of the corridor. To do this, the particle beam is surrounded by a sheathing beam, for example, for focusing purposes. This measure is at the same time used for silencing. If two or more nozzles or spray heads are used for the spraying process, these are disposed in a suitable manner and, in particular, can be switched on and off individually. Excess applied material, in particular copper powder, is removed by a cleaning process and is supplied to a processing system for reuse. In order to keep the undesirable oxide component of the copper small, the environment is formed by an inert gas such as nitrogen during the spraying process, for example by a sheathing beam or a transport beam.

The object is also achieved by a molding having a conductor run which is applied to a mount component using the described method, and is integrally connected to it. The advantages and preferred refinements that have been described with respect to the method can also be transferred to the molding in the same sense.

Other features which are considered as characteristic for the invention are set forth in the appended claims.

Although the invention is illustrated and described herein as embodied in a method for producing a molding with an integrated conductor run, and a molding, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A-C are diagrammatic, sectional views showing method steps for applying a conductor run to a mount component according to the invention;

FIG. 2 an exploded, a highly simplified view of a multilayer structure of a molding;

FIGS. 3A-3H are sectional views showing a number of intermediate stages in the process of producing the molding with integrated conductor runs;

FIGS. 4A-4G are sectional views showing a number of intermediate stages in the process of producing the molding with the integrated conductor runs having a multilayer structure;

FIG. 5A is an exploded view of the multilayer structure with a number of conductive levels disposed one above the other, with contact-making windows for contact-making pins;

FIG. 5B is a perspective view showing the contact-making pins which correspond to the contact-making windows shown in FIG. 5A;

FIG. 6A is an exploded view of the multilayer structure with a number of conductive levels, with an associated contact rod;

FIG. 6B is an enlarged perspective view of the contact rod;

FIG. 7A is a plan view of the molding with a number of integrated conductor runs, and with two integrated contact plugs;

FIG. 7B is sectional view through the molding shown in FIG. 7A along the section line VIIB-VIIB;

FIG. 8A is an exploded view of the multilayer structure shown in FIG. 2 with connecting conductors, which make contact with the conductor levels and with the conductor run;

FIG. 8B is an enlarged, sectional view of the contact area of a connecting conductor as shown in FIG. 8A;

FIG. 9A is a section view through the molding with the integrated conductor run, before a forming process;

FIG. 9B is a sectional view of the molding as shown in FIG. 9A, after a forming process;

FIG. 10 is a highly simplified illustration of a motor vehicle door as the molding with discrete conductor runs;

FIG. 11 is a highly simplified illustration of the motor vehicle door as the molding with large-area conductive levels;

FIG. 12 is a schematic illustration of a number of tool heads, which are operated in parallel, for a spraying method;

FIG. 13 is a perspective view showing a circuit mount assembly which is formed from two circuit mounts between which contact is made via contact pins;

FIG. 14 is a view of a component with contact elements that pass through it and make contact with conductor runs on both sides;

FIG. 15 is an illustration showing two mutually adjacent moldings with a compensating layer, which covers the abutment area between the two moldings; and

FIG. 16 is an illustration showing the principle of application of discrete conductor runs to the outer casing of the molding that is in the form of a flexible tube.

### DESCRIPTION OF THE PREFERRED EMBODIMENTS

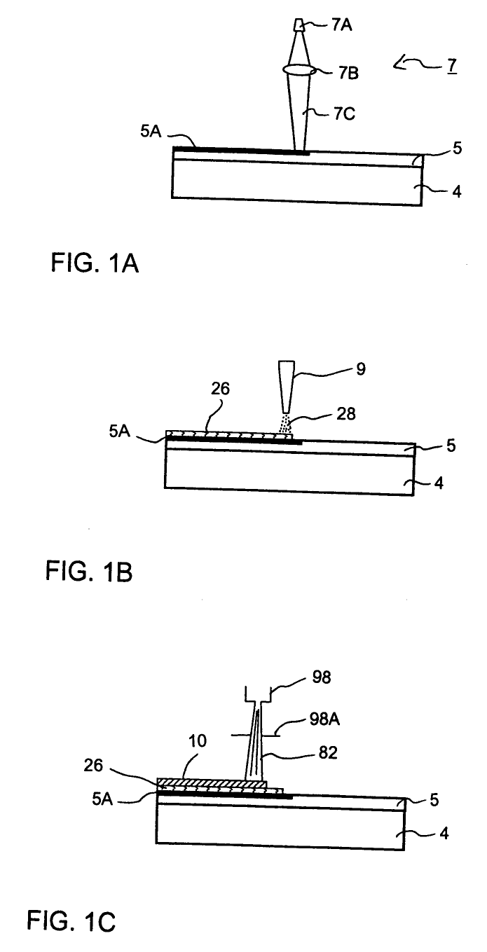

In all the figures of the drawing, sub-features and integral parts that correspond to one another bear the same reference symbol in each case. Referring now to the figures of the drawing in detail and first, particularly, to FIGS. 1A-1C thereof, there is shown the basic steps for producing a conductor run 10 on a mount component 4 and will be described by way of example. The mount component 4 has a surface layer 5 which, depending on the material of the mount component 4 and its suitability for forming an adhesion area 5A, was applied either directly to the surface of the mount component 4 or was applied as an autonomous surface layer in an extra method step. By way of example, the surface layer 5 is a painted layer. In the first step shown in FIG. 1A, the surface layer 5 is treated selectively, so that the adhesion characteristics of the surface layer are varied, and the adhesion area 5A is formed, in the treated area. An irradiation system 7 containing a radiation source 7A as well as a lens 7B for focusing a beam path 7C is, in particular, provided for this purpose. The radiation source 7A is a laser or a halogen lamp. The radiation source is used to introduce heat and to melt the surface layer 5A.

In the second step, as shown in FIG. 1B, a copper powder 28 is, in particular, applied to the adhesion area 5A with the aid of a supply tube 9, and is made to stick there. The applied powder 28 is used as a germination layer 26 for the conductor run 10 that is to be applied in the next step (FIG. 1C). The germination layer 26 is used as an adhesion promoter layer for good bonding of the conductor run 10 on the mount component 4. The germination layer 26 is thus referred to in the following text as a promoter layer. The first two steps can also be interchanged, so that the powder 28 is applied first, with the surface layer 5 being melted only after this has been done. In this case, the introduction of heat can also at the same time result in advantageous baking or melting, and close connection of the powder particles.

In the third step, the conductor run 10 is then applied by a spraying method, in particular by gas flame spraying. For gas flame spraying, the material to be applied, in particular copper, is heated in a nozzle 98 of a spraying head, and is at least partially melted, or made to start to melt. The copper is in this case supplied to the spray head in particular as a powder, whose grain size may cover a wide range from about 5 μm to a few millimeters. The speed of the particles is in the meters per second range and may reach the speed of sound, particularly for cold gas spraying. The particles are in this case sprayed onto the mount component 4 as a particle beam 82 that is carried by an inert carrier gas. A mask 98A is provided for focusing the particle beam 82. In order to produce the conductor run 10, the spray head is moved relative to the mount component 4, in which process high speeds of movement in the region of several meters per second (for example 2-10 m/s) or more can be achieved.

Gas flame spray has the major advantage that it allows a complex conductor run structure to be applied to the mount component 4 very quickly and, in particular, in a manner that can be automated. This makes it possible to replace a complex manual laying of individual cables for a motor vehicle power supply system. Furthermore, the mount component 4 may have virtually any desired configuration. Gas flame spray is thus also suitable for producing the germination layer.

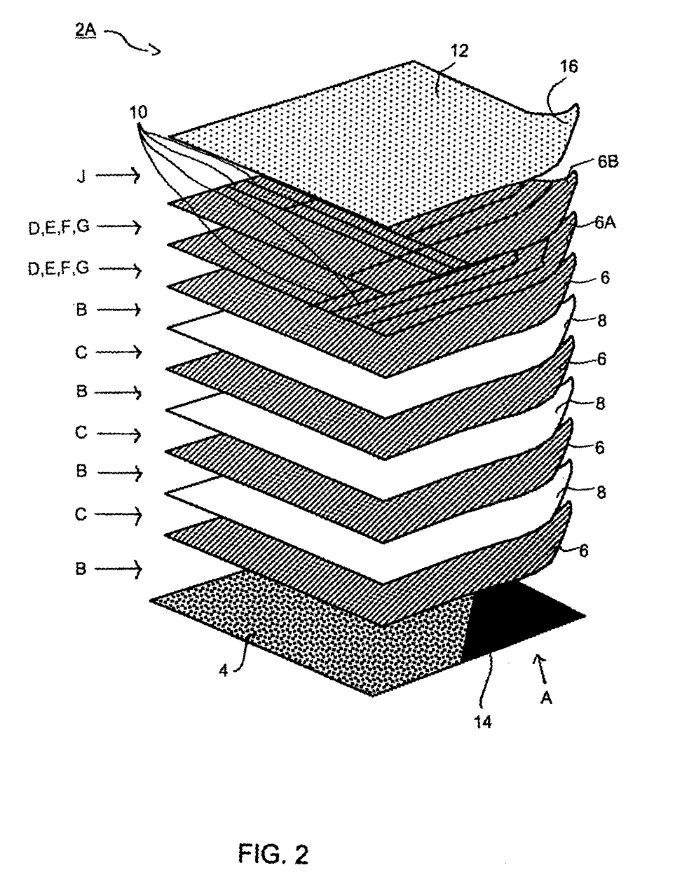

FIGS. 2 to 6 show various variants of a complex molding with the mount components 4, and the production of the conductor run 10. The moldings together with the integrated conductor runs are generally produced in a number of method steps. The production process may in this case be subdivided into the following basic method steps that are carried out partially, alternatively or in combination.

| | |
|---|---|
| Method step A: | Preparatory measures for producing a |
| | loose subarea of the conductor run; |
| Method step B: | Application of an insulation layer; |
| Method step C: | Application of a conductive level; |
| Method step D: | Application of a surface material; |
| Method step E: | Treatment of the surface material in |
| | order to change the adhesion charac- |
| | teristic; |
| Method step F: | Application of a promoter layer; |
| Method step G: | Application of the conductor run; |
| Method step H: | Rinsing or fixing process, and |
| Method step I: | Application of a protective layer. |

Each of the letters A to I which represent the individual method steps and show which method steps are used for the various variants of the moldings.

FIG. 2 shows only a square, exploded detail of a molding 2A that has a multilayer structure. Isolation layers 6 and conductive levels 8 follow one another in an alternating sequence on the mount component 4. The last of the total of three conductive levels 8 which are shown is bounded by an isolation layer 6 to which two further isolation layers 6A, 6B are applied, added to which two or more conductor runs 10 are applied. The multilayer structure is closed at the top by a protective layer 12.

Method steps D to G are used in particular to apply the conductor runs 10. The conductor runs 10 have an elongated, discrete profile. In contrast, the conductive levels 8 have a large area and are formed without any preferred direction. They thus form a conductor run as a level that has no discrete profile. In fact, contact can be made with each of the conductive levels 8 at any desired positions.

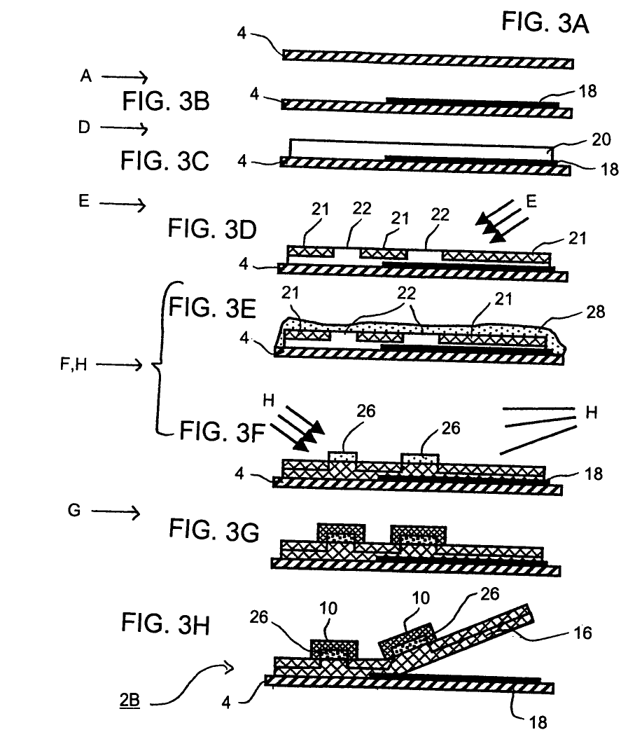

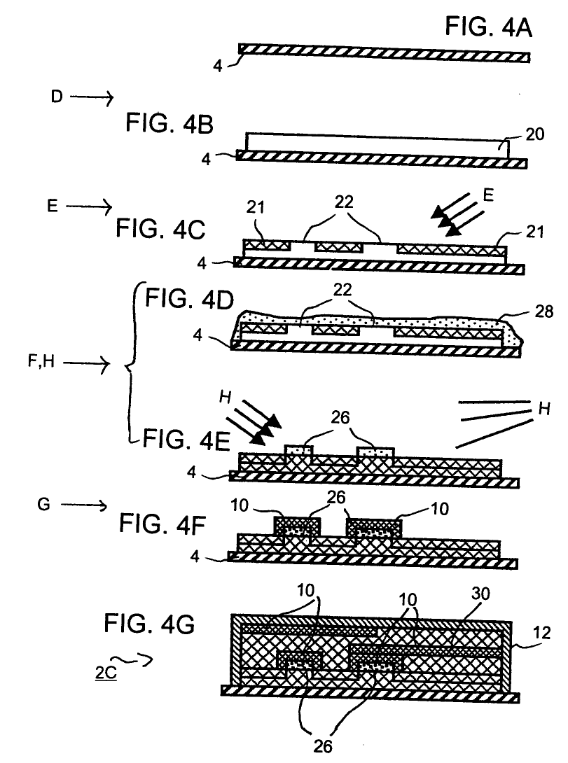

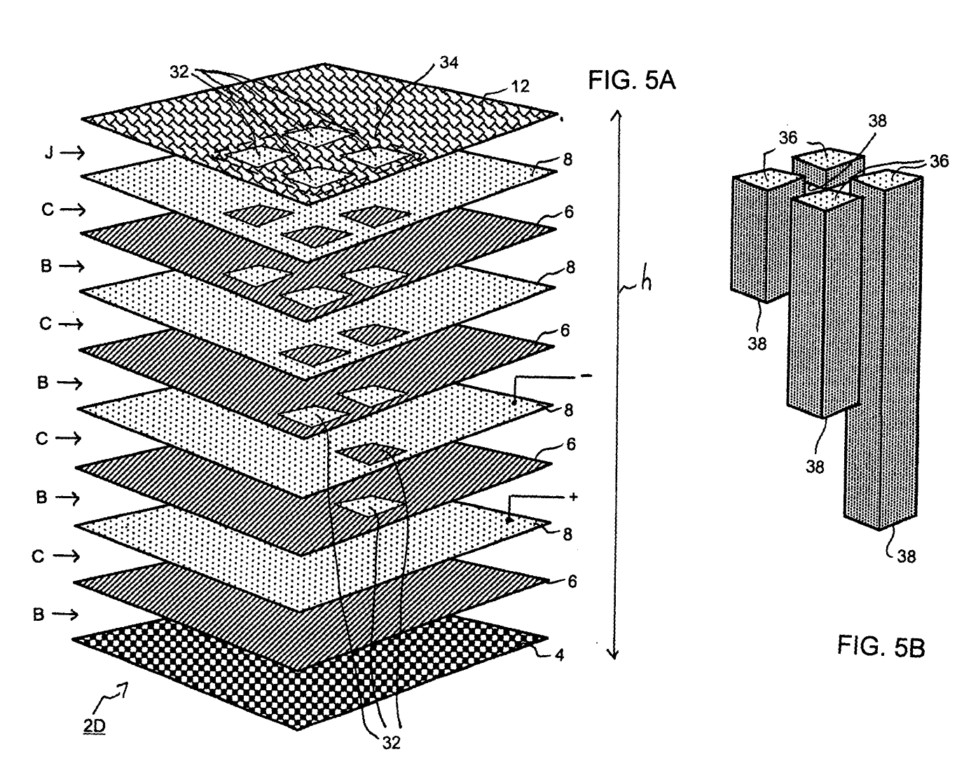

The multilayer structure shown in FIG. 2 accordingly represents a combination of a discrete conductor run pattern, represented by the isolation levels 6A and 6B, and the configuration of large-area conductive levels 8. The variant with the discrete conductor run pattern will be explained in more detail in particular with reference to FIGS. 2-3H, and the variant with the conductive levels 8 will be explained in more detail in particular with respect to FIGS. 4A-5.

As is shown in FIG. 2, the mount component 4 also has an isolating layer 14 in a corner area, and the isolating layer 14 is applied by the method step A. The isolating layer 14 allows the multilayer structure that is applied to the mount component 4 to be partially lifted off. A subarea 16 of the multilayer structure is thus connected loosely rather than firmly to the mount component 4. The loose subarea 16 is illustrated by a corner of the individual layers applied to the mount component 4 being bent upwards. The configuration of the loose subarea 16 will be explained in more detail in particular with reference to FIGS. 3A-3H and 10.

The procedure for producing a molding 2B with a discrete conductor run structure as shown in FIGS. 3A-3H is as follows. An isolating element 18 is first applied to the mount component 4, for example to a panel of the motor vehicle door, only partially covering the mount component 4 (method step A and FIG. 3B). Alternatively, an isolating layer 14 can also be applied. The mount component 4 and the isolating element 18 are then coated with a surface material. A rubber coating 20 is used in particular as the surface material (method step D, FIG. 3C). The surface material is then irradiated selectively, that is to say in a locally limited manner, in the method step E, FIG. 3D. In this case, a laser is used in particular as the radiation source. The irradiation results in cross-linking of the rubber, which was initially not in a cross-linked form in the rubber coating 20, forming cross-linked surface areas 21 whose surface now has only a low level of adhesion. Those areas that are not irradiated still have the original high adhesion and each form discrete areas of a conductor run structure 22, whose profile corresponds to the desired profile of the conductor run 10 to be applied.

In the next method step F (FIGS. 3E, 3F), the germination or promoter layer 26 is applied to each conductor run structure 22. The procedure for this has two stages. In a first stage, the powder 28 composed of a conductive material is applied simultaneously over the cross-linked surface areas 21 and those areas of the conductor run structure 22 that have not been cross-linked. The powder 28 is, for example, a copper powder. The powder 28 sticks to the conductor run structure 22. The excess powder 28 is removed from the remaining surface areas 21 that have already been cross-linked, in a rinsing process (method step H). This is done, for example, by blowing a powder off with compressed air. Those areas of the conductor run structure 22 which have not yet been cross-linked are cross-linked by a fixing process (likewise method step H), for example by thermal radiation. This improves the bonding of the powder 28 to the rubber coating 20, and hence to the mount component 4. The promoter layer 26 that is formed is used as an adhesion promoter between the mount component 4 and the conductor run 10.

The actual conductor run 10 is applied to the promoter layer 26 in the next method step G (FIG. 3G). This is preferably done by gas flame spray or, for example, by applying conductive material from a melt by wave soldering. As an alternative to this, there are also possible ways to apply a paste with a conductive material, or to apply the conductive material from a gas or from a plasma. Furthermore, the conductor runs 10 can be formed as conductive strips using a form of lamination process. Excess conductive material can subsequently likewise be removed by a rinsing process.

Since a copper powder 28 is first scattered onto the conductor run structure 22 in the described exemplary embodiment, the layer that is referred to as the promoter layer 26 is already conductive. Owing to the large number of grain boundaries and the fact that the layer may only be very thin, one problem that arises in this case, however, is that the conductivity may be only low. In an alternative variant, the conductivity of powder grains is increased by baking, owing to the thermal influence between the individual powder grains, so that the promoter layer 26 is itself in the form of a conductor run 10. Generally, the conductor run 10 is additionally coated with conductive material in order to increase the conductivity. In principle, the same methods as those for application of the conductor run 10 are suitable for this purpose.

The structure formed in this way rests only loosely on the mount component 4 in the area of the isolating element 18, that is to say it is not firmly connected to it. The subarea 16 can thus be lifted off the mount component 4. The loose subarea 16 is particularly suitable, for example, for making contact with a plug, since the subarea 16 can simply be inserted into the plug (FIG. 3H).

The structure that is formed is preferably compressed under pressure, in particular in order to improve the adhesion between the individual layers.

The construction of a molding 2C as shown in FIGS. 4A-4G is based essentially on carrying out the same steps as those for the molding 2B shown in FIGS. 3A-3H. In contrast, the conductor runs 10 on the molding 2C shown in FIGS. 4F-4G are disposed one above the other in a number of layers. The molding 2C is thus characterized by a multilayer structure of discrete conductor runs 10.

The multilayer structure of the molding 2C differs from the multilayer structure shown in FIG. 2 in that discrete conductor runs 24 are now disposed in a number of layers one above the other. In contrast, the multilayer structure shown in the molding 2A in FIG. 2 has a sequence of discrete conductor run patterns between isolation layers, conductive levels 8 and the isolation layers 6A, 6B. In any case, the two isolation layers 6A, 6B which are located one above the other and have the discrete conductor run patterns have a multilayer structure which is comparable to that of the molding 2C shown in FIGS. 4A-4G.

The multilayer structure results in a three-dimensional conductor run pattern. In this case, some of the individual conductor runs 10 can be connected to one another by cross connections 30, in order to produce even complex wiring patterns.

The three-dimensional structure is formed by repeating the method steps B to G after application of the conductor runs 10 in the first level. Therefore, the rubber coating 20 is once again applied after application of the conductor runs 10 in the first level. If the conductor runs 10 in two successive levels are intended to make contact with one another, then the rubber coating 20 is removed once again in the contact area between the two conductor runs, for example between the cross connection 30 and the conductor run 10 located underneath it, or the application of the rubber coating 20 is prevented by use of a mask.

The multilayer structure is entirely surrounded by the protective layer 12. This is preferably used both for isolation and corrosion protection purposes and is preferably a layer composed of PU material.

The molding 2D, only square details of which are illustrated in FIG. 5A, has an alternating sequence, in a similar way to that illustrated in FIG. 2, of the isolation layers 6 and the conductive layers 8, which are applied to a mount component 4. The layer structure is closed by the protective layer 12. The conductive levels 8 are each part of an electrical vehicle power supply system, and each carry out different functions. Two of the conductive levels are advantageously in this case used for the voltage supply, that is to say one of the conductive levels 8 is at a positive potential and another of the conductive levels 8 is at ground potential. The two further conductive levels 8 that are illustrated are preferably still used as data bus lines.

The multilayer structure preferably extends over the entire molding 2D. As an alternative to this, only subareas of the layer structure may also be covered. In addition, different subareas may also have layer structures that are isolated from one another as well as different layer structures. The essential feature is that the individual conductive levels are applied to the mount component 4 over a large area and without any preferred orientation. In principle, this refinement allows contact to be made at all the points on the molding 2D. This allows very flexible handling and positioning of electrical components to be connected, since they can be positioned virtually as desired on the molding 2D. Since the electrical components are, furthermore, not all provided with their own supply cable, the illustrated layer structure allows a very compact and space-saving configuration. This has enormous advantages, particularly in the dashboard area where a large number of electrical components have to be connected, since the small amount of space that is available there is not congested by a wide range of cables and connectors.

The large-area extent of the conductive levels 8 results in that they may be formed thinner than the discrete conductor runs 10, since the very large area ensures adequate conductivity.

Contact-making windows 32 are provided in some of the individual layers 6, 8, 12 and are grouped in a contact area 34, in order to make contact with the individual conductive levels 8. The contact-making windows 32 are in this case disposed such that a corresponding contact-making pin 36 can be passed through for each of the conductive levels 8 (FIG. 5B). The contact-making pins 36 in this case each have a touching contact surface 38 on their lower end face that, once contact has been made, rests on the respective conductive level 8. For any given conductive level 8, a contact-making window 38 that is associated with the conductive level 8 is in each case disposed in all of the layers 6, 8, 12 that are disposed above the level 8. The number of contact-making windows 32 which are disposed alongside one another thus increases upwards in the direction of the protective layer 12. The protective layer 12 has a total of 4 contact-making windows 32.

A number of contact areas 34 are preferably provided over the surface of the molding 2D, so that the individual conductive levels 8 can make contact via the contact pins 36 with a large number of positions. The contact areas 34 may in this case be disposed distributed as required over the surface, in order to allow contact to be made with electrical components at any desired points.

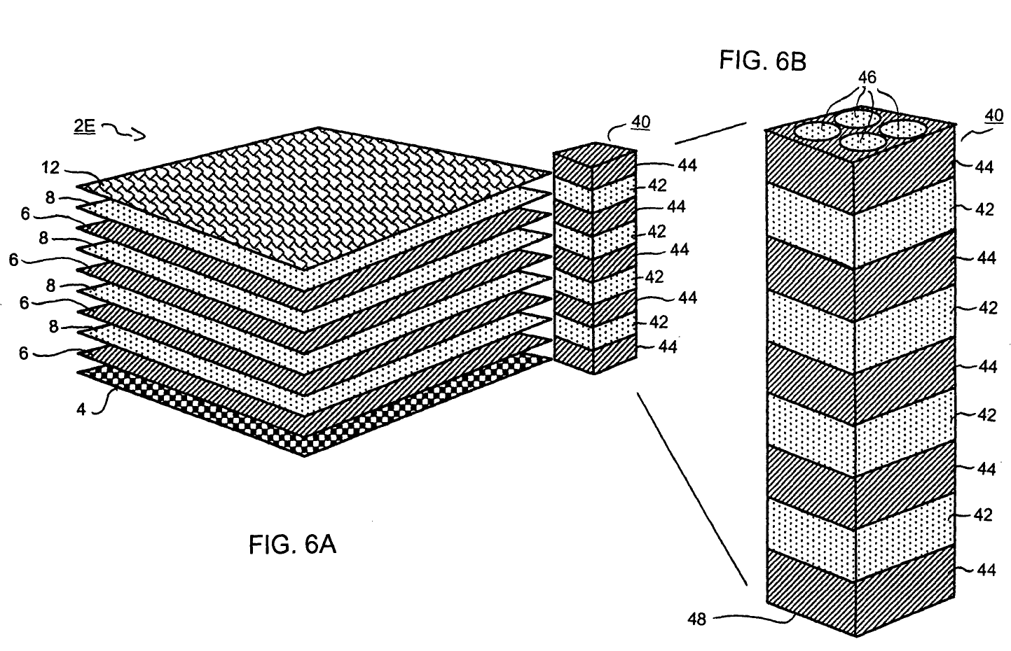

As an alternative to the configuration of the contact-making pins 36 with touching contact surfaces 38 on the end faces, a contact rod 40 is provided, as is illustrated in FIG. 6B. This has two or more contact zones 42 that are distributed over its length and are isolated from one another by isolation zones 44. The alternating structure between the isolation zones 44 and the contact zones 42 corresponds to the alternating structure of the molding 2E as illustrated in FIG. 6A. Each of the individual contact zones 42 is connected to a supply line 46 via which, for example, contact is made with an electrical component. For the contact rod 40 to make contact with the individual conductive levels 8, it is preferably in the form of an insulation-displacement contact rod that is driven into the layer structure of the molding 2E using a type of “piercing” method. To do this, the contact-making rod is equipped with a non-illustrated cutting point at its lower end 48. The individual contact zones 42 in this case make contact with the individual conductive levels 8. The “piercing” method has the advantage of high contact reliability, since the contact rod 40 is clamped in by the individual conductive levels 8. It is also possible to make contact with any desired positions in the molding 2E. As an alternative to this, a contact-making window 32 is likewise provided for the contact rod 40, through which the contact rod 40 is pushed into the multilayer structure.

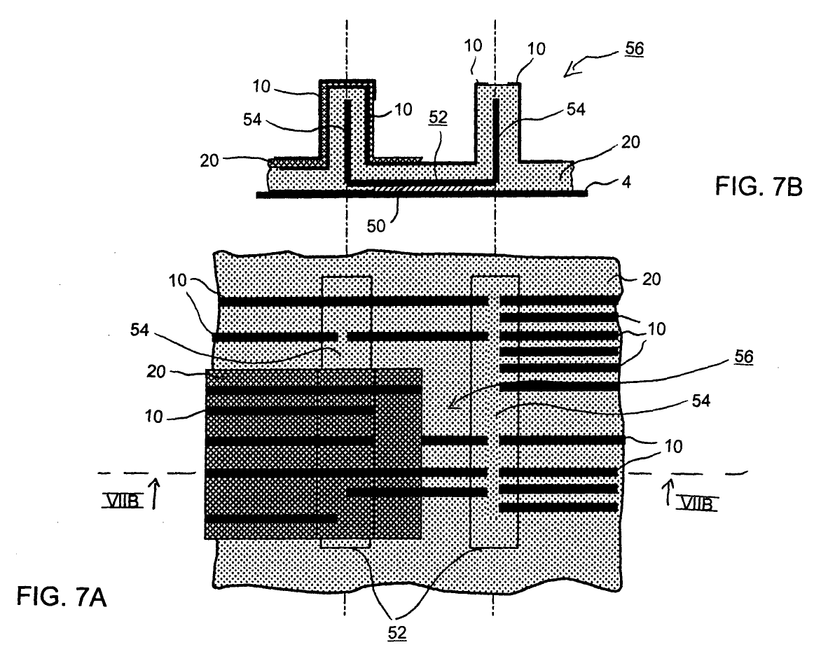

A further variant for providing a contact-making capability, namely with the aid of a contact plug 56, is illustrated in FIGS. 7A and 7B. The contact plug 56 will be explained with reference to a discrete conductor run pattern, but it is also equally suitable for making contact with flat conductive levels 8.

As can be seen in particular from FIG. 7B, a plug molding 52 is applied to the mount component 4, for example by an adhesive layer 50. The mount component 4 is then covered, together with the plug molding 52, with the rubber coating 20. This process is then followed, for example, by method steps for producing the conductor runs 10, as has already been described for the multilayer structure, in particular with reference to FIGS. 4A-4G. The plug molding 52 in the exemplary embodiment has a U-shaped cross section and has two elongated webs 54, whose length extends over two or more of the conductor runs 10, as can be seen from FIG. 7A. The contact plug 56 is formed at the location of the plug molding 52 by covering the plug molding 52 with the subsequent layer structure, in particular with the conductor runs 10. Connecting lines can be connected to the individual conductor runs 10 in the raised positions on the contact plug 56 in a simple manner, with the aid of a connecting plug which is configured to be complementary to the contact plug 56. At the same time, it is possible for a connecting plug such as this to be in the form of a functional plug, which carries out further functions in addition to the pure contact-making functions. For example, a functional plug such as this may link specific conductor runs 10 in the conductor run pattern to one another in order to enable or to block specific electrical functions in the motor vehicle.

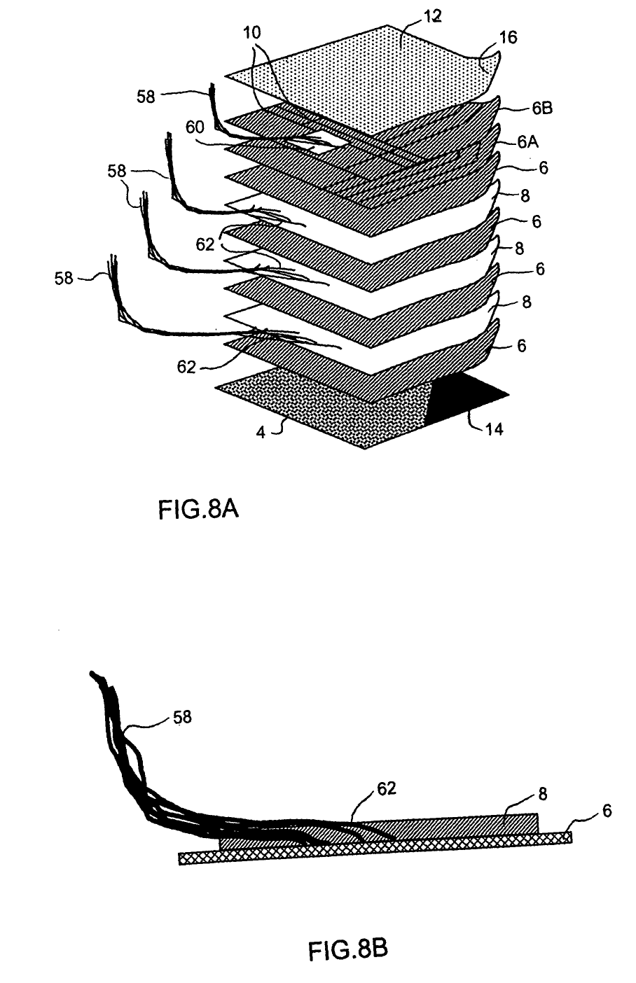

A particularly simple contact-making option for a connecting conductor 58 is illustrated in FIGS. 8A and 8B. FIG. 8A in this case shows a detail of a molding 2F, which has the same multilayer structure as the molding 2A shown in FIG. 2. In contrast to the molding 2A illustrated in FIG. 2, two or more connecting conductors 58 are now electrically connected directly to the conductive levels 8 and to one of the conductor runs 10 in the isolation layer 6B. A contact surface 60 composed of electrically conductive material is applied to the isolation layer 6A in order to allow the connecting conductor 58 to make contact with the corresponding conductor run 10 in the isolation layer 6A. In this case, the contact surface 60 covers a piece of the conductor run 10 with which contact is to be made, and is electrically conductively connected to it.

Contact is made with the connecting lines 58 during the formation of the layers. In the procedure to do this, the conductor ends 62 of the connecting lines 58 are placed on the isolation layer 6, which is located at the top in this particular method step, and the conductive levels 8 are then applied by a coating process. This results in a direct integral connection between the conductive level 8 and the conductor ends 62. In order to ensure that a reliable contact is made, the conductor ends 62 are preferably shaped suitably in order to provide a contact area that is as large as possible. To do this, the conductor ends 62 are, for example, provided with recesses or windows, or are beveled or have a particular profile, such as a dovetail profile.

This procedure is also used to make contact with the discrete conductor run 10. The conductor ends 62 are thus placed on the isolation layer 6B and the contact surface 60 is then applied by a coating method, so that the conductor ends 62 on the one hand and the conductor run 10 with the contact surface 60 on the other hand are each integrally connected to one another.

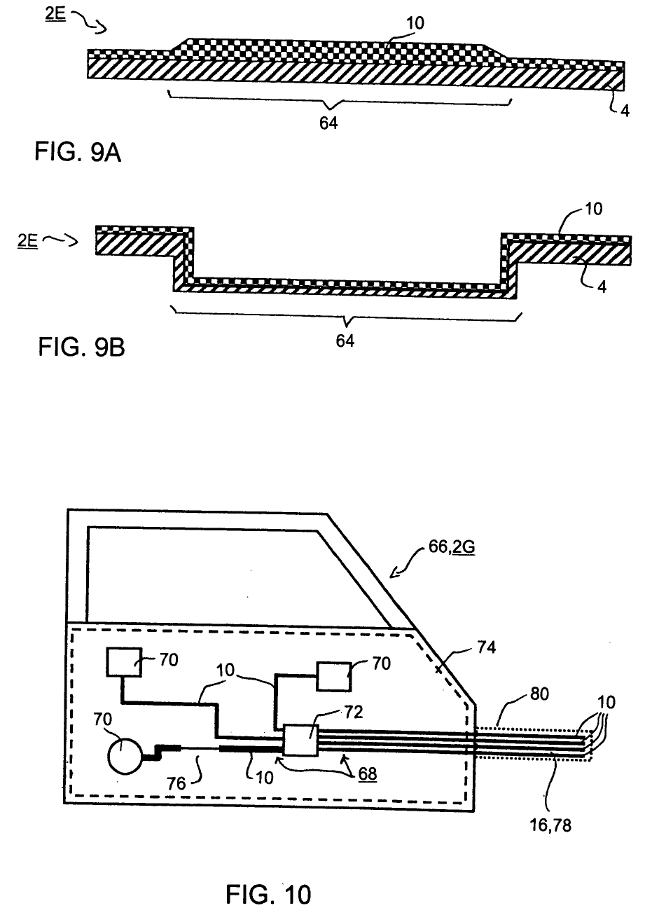

In the field of motor vehicles, the moldings 2 often have a complex geometry with a surface to which access for a coating process is difficult. According to one refinement, which will be explained with reference to FIGS. 9A and 9B, the conductor run 10, an entire conductor run pattern or else a complete layer structure as described with reference to the preceding figures is thus applied to a preferably flat, planar mount component 4. As an alternative to this, the mount component 4 may also already be preformed. The important feature is that the surface of the mount component 4 is accessible sufficiently easily for the various coating processes. The molding 2E formed in this way is then changed to the desired final shape by a forming process, as is illustrated schematically in FIG. 9B. While the conductor run 10 is being applied to the initially planar mount component 4, the dimensions of the conductor run 10 in a forming area 64 are set so that the conductor run 10 will have the desired electrical characteristics after the forming process. According to the exemplary embodiment shown in FIGS. 9A and 9B, this is achieved by the conductor run 10 being configured to be thicker in the forming area 64 before the forming process than in the adjacent areas. The thickness in the forming area 64 is in this case of such a size that a homogeneous and constant thickness of the conductor run 10 is achieved after the forming process, as is illustrated in FIG. 9B.

FIG. 10 shows the application in which a molding 2G is a motor vehicle door 66. A cable harness 68 is integrally connected to the door 66 and has a number of individual conductor runs 10, via which individual electrical components 70 are connected. The electrical components are, for example, a motor for an electric window winder, a loudspeaker or an apparatus for central locking. A controller 72 is also disposed. The individual components 70 are operated by the controller 72. The individual conductor runs 10 in the cable harness 68 are, for example, directly connected to a bodywork panel of the door 66. As an alternative to this, the cable harness 68 may also be integrated in what is referred to as a door module 74, which is connected as such to the doors 66. A door module 74 such as this is a molding and is illustrated by dashed lines in FIG. 10.

One of the illustrated conductor runs 10 has a tapered intermediate section 76, in which the cross-sectional area of the conductor run 10 is reduced. The intermediate section 76 thus forms an electrical function component in the form of a resistor. Functional components such as these can easily be produced by virtue of the production method. As shown, the desired resistance can be set precisely, for example by variation of the conductor run width. In addition, the conductor runs 10 may also be in the form of antennas, capacitors or coils.

A pigtail 78, which projects beyond the molding 2G, is provided for a simple connection of the cable harness 68 to the rest of the power supply system in the motor vehicle. When producing the pigtail 78, an extension 80 that is represented by dots, is connected to the molding 2G, and the conductor runs 10 are then applied to the extension 80, so that the conductor runs 10 extend from the molding 2G to the extension 80. The pigtail 78 represents a further alternative for the configuration of a loose subarea 16 (method step A) in addition to the variants with the isolation layer 14 (FIG. 2) and the isolation element 18 (FIG. 3B).

The direct integration of the conductor run 10 on the surface of the mount component 4 results in the conductor run 10 being mechanically firmly connected to the mount component 4, with only a small physical height. The small physical height makes it possible to pass the conductor run 10 around the edges of a panel underneath a seal, as well. This is of interest, for example, for what is referred to as a door module mount, on which two or more electrical components such as window winders, loudspeakers etc. are integrated. The conductor run 10 may in this case, specifically, be passed around an edge under a seal that seals an outer wet area from an inner dry area. Therefore, there is no need to provide complex cable bushes, which need to be sealed, from the wet area to the dry area.

The mechanically firm connection to the mount component 4 also ensures a certain degree of protection against theft since, for example, it is impossible to short two loose connectors. For additional protection, the conductor run 10 may additionally be coated by a blocking layer (which, in particular, is conductive and is grounded) with the interposition of an isolation layer.

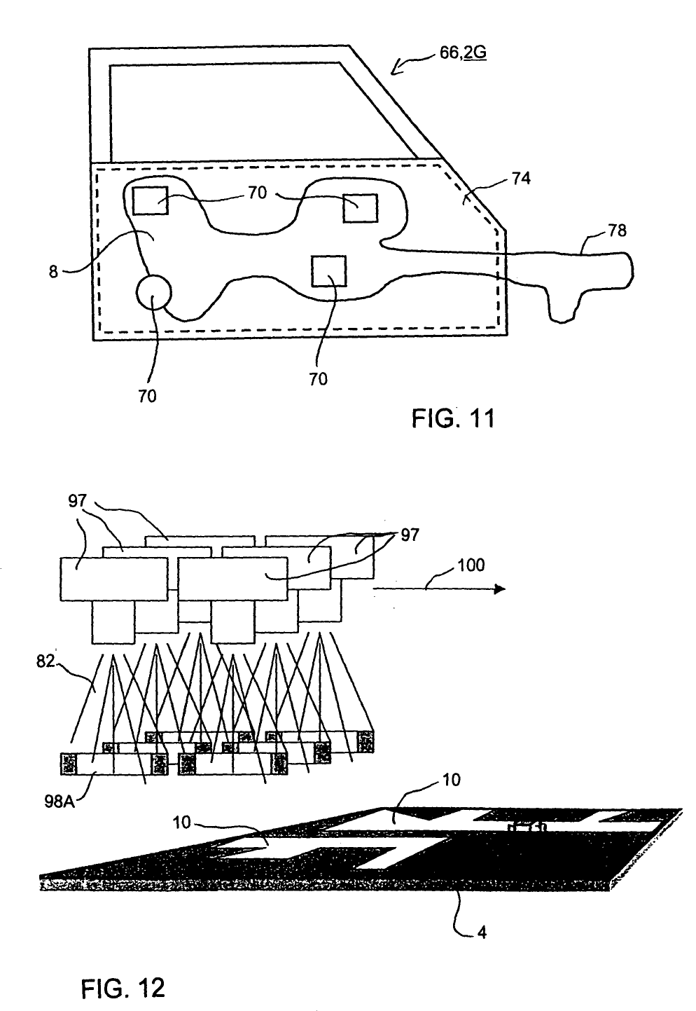

As an alternative to the embodiment variant as illustrated in FIG. 10 with the discrete conductor runs 10, a multilayer structure composed of conductive levels 8 for the door 66 is provided in FIG. 11, as is illustrated by way of example in FIGS. 2, 5 or 6. The multilayer structure in this case contains either exclusively a sequence of conductive levels 8 or else a combination between conductive levels 8 and a conductor run pattern with discrete individual conductor runs 10.

As shown in FIG. 12, two or more tool heads 97 are disposed in a grid alongside one another in order to produce the conductor runs 10, in particular by gas flame spraying. Each of the tool heads has the associated mask 98A. The tool heads 97 are operated at the same time, and each can be switched on and off individually. The grid configuration allows two or more conductor runs 10 and complex conductor run structures to be produced very quickly.

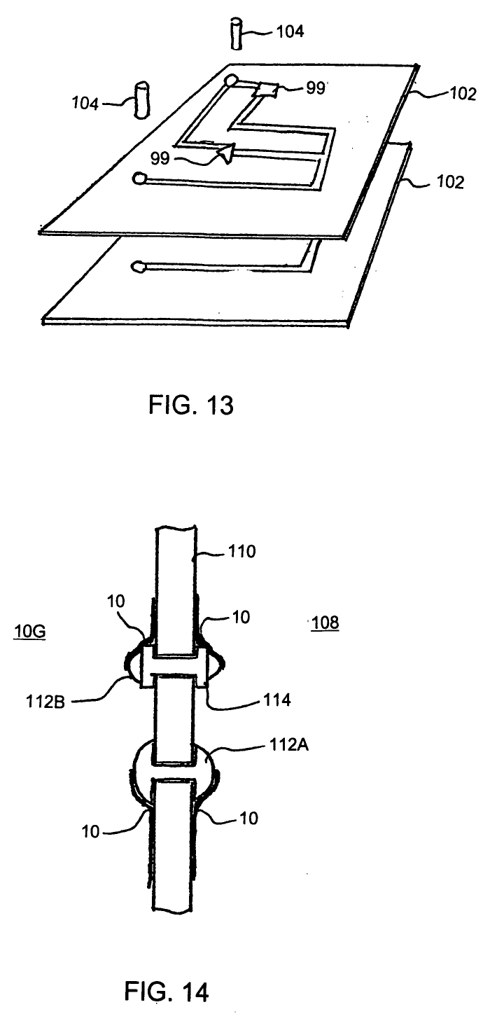

FIG. 13 shows an exploded illustration of two circuit mounts 102 which form a circuit mount assembly and on which components 99 are disposed which are connected via conductor runs. The two circuit mounts 102 have contact made through them via a contact element or direct contact pins 104, that is to say they are electrically connected to one another. The circuit mounts 102 are, for example, in the form of printed circuit boards or, in general form, are in the form of printed conductor run or conductor track patterns. The contact pins 104 are used to make contact between the circuit mount and a conductor run 10 (not shown in FIG. 13), that is to say the conductor run 10 is connected to the contact pins 104. These are formed, for example, in the same way as the contact-making pin 36 described with reference to FIG. 5B, or in the same way as the contact rod 40 described with reference to FIG. 6B. In this case, the contact is in particular formed directly during production of the conductor run 10, for example by gas flame spraying. In the process, a direct integral connection is produced between the conductor run 10 and the contact pins 104. Contacts to electrical components, such as motors or loudspeakers, can also be produced in the same way.

As an alternative to the conventional way of making contact with the components 99 on the circuit mount 102 (printed circuit board) is, for example by soldering, the components 99 can advantageously also be made contact with quickly and easily by the gas flame spraying process. For this purpose, the conductor run 10 that is produced by the gas flame spray is drawn over corresponding contact feet of the components. In addition to making contact with the components 99, a conductor run pattern can also be produced by gas flame spraying on the circuit mount 102.

In the field of motor vehicles, an electrical cable often has to be passed from a wet area 106 to a dry area 108 through a component 110 (FIG. 14). The component 110 is, for example, a door panel or the internal lining on a door. The bushing for the cable through the component 110 must be moisture tight. Conventionally, rubber grommets are provided for this purpose, through whose cavity individual wire cables are passed. As is shown in FIG. 14, the invention provides for a contact element 112A, B to be passed through the component 110 forming a seal. In this case, FIG. 14 shows two alternative refinements of a contact element 112A, B. The contact element 112A that is illustrated in the lower half of FIG. 14 is in the form of a soft rivet, which is passed directly through the component 110. In contrast, the contact element 112B for the component 110 is also once again sealed specifically for example by an isolating or rubber sleeve 114. The contact element 112B is in this case passed through the rubber sleeve 114. The rubber sleeve 114 is required in particular when the component 110 is itself conductive, so that the contact element 112B must be isolated from the component 110. Conductor runs 10 are each made contact with directly on both sides on the contact elements 112A, B, thus resulting in an electrical connection from the wet area 106 to the dry area 108.

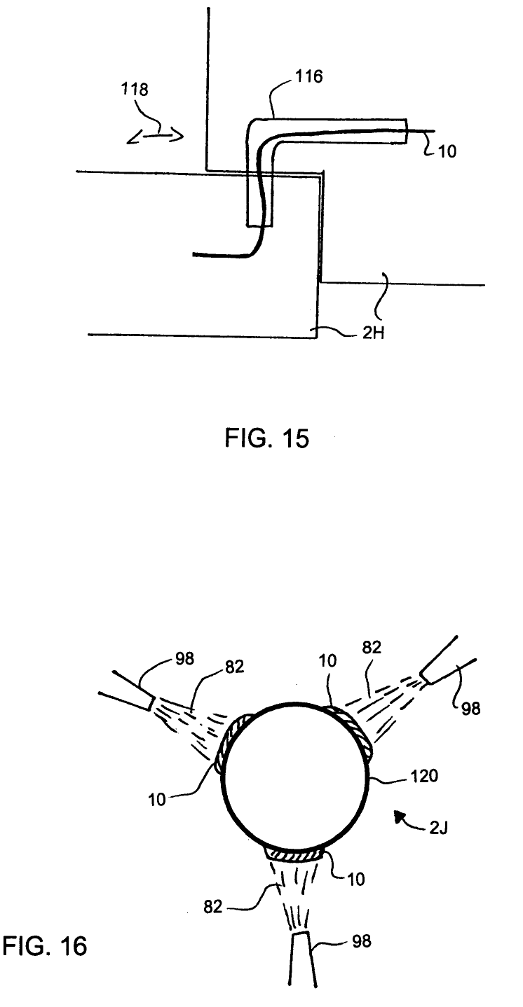

As is shown in FIG. 15, the conductor run 10 is passed over an abutment area between two mutually adjacent moldings 2H. In the abutment area of the two moldings 2H, the conductor run 10 is applied to a compensating layer 116, which is in each case mounted only in a floating manner on the two moldings 2H, that is to say it rests only loosely on them. Adjacent to the compensating layer 116, the conductor run 10 is firmly connected to the respective moldings 2H. If a torsional stress in a transverse direction 118 occurs, between the two moldings 2H, for example because of mechanical or thermal loads, then the torsional stress is absorbed by the compensating layer 116 which, in particular, is configured to be flexible, and is not transmitted to the conductor run 10. The compensating layer 116 is, in particular, a rubber coating that is removed from the mount components 4 of the respective moldings 2H by an appropriate subsequent treatment, in particular cross-linking.

The conductor run 10 may also be applied to elongated moldings 2J that are not flat. FIG. 16 shows a flexible tube 120 as the mount component for the application of the conductor run 10. A total of three conductor runs 10 are applied to the outside of the flexible tube 120 by a spraying method. For this purpose, nozzles 98 are disposed at 120° intervals around the flexible tube 120, and the particle beam 82 emerges from the nozzles 98. The flexible tube is, for example, the outer sheath of a conventional cable, in particular a cable embedded in foam.

Instead of forming the conductor runs 10 discretely, it is also possible to use the spraying method to form a continuous conductive coating over the flexible tube 120. It is also possible to apply a conductor run 10 such as this to the inner surface of the flexible tube 120. In this case, the conductor run 10 is actually applied during the process of extruding the flexible tube 120 that is formed, in particular from plastic. In this case, the mouthpiece of the extrusion tool is configured appropriately and, in particular, has a centrally disposed nozzle that extends into the interior of the flexible tube.

We claim:

1. A production method, which comprises the steps of:
providing a motor vehicle molding for producing an end product selected from the group consisting of doors, door modules, door panels, dashboard parts, and dashboards;
treating a surface of the motor vehicle molding selectively in a manner corresponding to a profile provided for a conductor run, such that the surface has areas of different adhesion;
applying a germination layer to the profile provided for the conductor run; and
applying the conductor run to the germination layer resulting in the conductor run being integrally connected to the motor vehicle molding.

2. The method according to claim 1, which further comprises applying the conductor run using a beam thermal/kinetic application method.

3. The method according to claim 2, which further comprises using an inert gas as a carrier gas for a particle beam for the beam thermal/kinetic application method.

4. The method according to claim 3, which further comprises adding conductive particles and nonconductive impurities to the particle beam.

5. The method according to claim 1, which further comprises applying the conductor run from a melt, and the motor vehicle molding being drawn together with the germination layer through a melt bath to apply the conductor run.

6. The method according to claim 1, which further comprises carrying out at least two of the method steps using one processing apparatus.

7. The method according to claim 1, which further comprises varying an adhesion characteristic of the surface of the motor vehicle molding by performing one of the steps of:
coating the surface with a substance which can be cross-linked and the substance having an adhesion characteristic varied by subsequent locally selective cross-linking;
coating the surface with a substance which can be cured and the substance having an adhesion characteristic varied by subsequent locally selective curing;
applying a chemically active substance that varies an adhesion characteristic of the surface;
treating the surface by supplying heat;
electrostatically charging the surface; and
selectively applying an adhesion layer to the surface.

8. The method according to claim 1, which further comprises applying the germination layer by one of the steps of:
applying a powder to the surface;
drawing the motor vehicle molding through a powder bath; and
applying a metallic suspension to the motor vehicle molding.

9. The method according to claim 1, which further comprises forming the germination layer with interruptions in the profile provided for the conductor run.

10. The method according to claim 1, which further comprises:
connecting a compensating layer to the motor vehicle molding in a floating manner; and
applying the conductor run partially on the compensating layer.

11. The method according to claim 1, which further comprises varying a material structure of the conductor run.

12. The method according to claim 1, which further comprises coating the conductor run after the conductor run is applied for at least one of increasing a conductivity and providing a protective layer.

13. The method according to claim 1, which further comprises applying the conductor run such that an electrical functional component is produced.

14. The method according to claim 1, which further comprises applying at least two conductor runs which are isolated from one another and are disposed one above another in layers.

15. The method according to claim 1, which further comprises forming large-area conductive levels which are disposed in layers, the large-area conductive levels forming part of an electrical power supply system, and carry out different functions for the electrical power supply system.

16. The method according to claim 1, which further comprises applying the conductor run such that it can be disconnected from the motor vehicle molding.

17. The method according to claim 15, which further comprises applying a structure selected from the group consisting of an insulating layer and an insulating element before an application of the conductor run.

18. The method according to claim 1, which further comprises applying an extension to the motor vehicle molding, and applying the conductor run from the motor vehicle molding, extending to the extension, for forming a pigtail.

19. The method according to claim 1, which further comprises placing one conductor end of a connecting conductor on the motor vehicle molding and the connecting conductor is electrically conductively connected to the conductor run when the conductor run is subsequently applied.

20. The method according to claim 1, which further comprises:
fitting a plug molding to the motor vehicle molding; and
subsequently coating the plug molding, at least partially, with a piece of the conductor run, thus producing a contact plug.

21. The method according to claim 1, which further comprises contacting the conductor run with a mount selected from the group consisting of a circuit mount having a contact element and a circuit mount assembly having a contact element, and the conductor run makes contact with the contact element.

22. The method according to claim 2, wherein the conductor run produced by the beam thermal/kinetic application method makes contact with an electrical component.

23. The method according to claim 1, which further comprises changing the motor vehicle molding to a desired final shape by a forming process after an application of the conductor run.

24. The method according to claim 23, which further comprises dimensioning the conductor run in a forming area of the motor vehicle molding such that the conductor run has a desired electrical characteristics after the forming process of the motor vehicle molding.

25. The method according to claim 2, which further comprises using a gas flame spraying process as the beam thermal/kinetic application method.

26. The method according to claim 4, which further comprises using silicon as the nonconductive impurities.

27. The method according to claim 1, which further comprises applying at least one further conductor run to the germination layer and the conductor run and the further conductor run form an electrical functional component.

28. A motor vehicle molding, comprising:
a conductor run;
a molding body for producing an end product selected from the group consisting of doors, door modules, door panels, dashboard parts, and dashboards, said molding body having a surface treated selectively in a manner corresponding to a profile provided for said conductor run, such that said surface has areas of different adhesion; and
a germination layer applied to the profile provided for said conductor run, said conductor run applied to said germination layer and thereby being integrally connected to said molding body.
